(19) United States
(12) Patent Application Publication
(10) Pub. No.: US 2010/0048023 A1
(43) Pub. Date: Feb. 25, 2010

(54) Methods for Manufacturing a Structure on a Substrate and Intermediate Product

(76) Inventors: Christoph Noelscher, Nuernberg (DE); Rolf Weis, Dresden (DE)

Correspondence Address: SLATER & MATSIL, L.L.P., 17950 PRESTON ROAD, SUITE 1000, DALLAS, TX, 75252, US

(21) Appl. No.: 12/196,474

(22) Filed: Aug. 22, 2008

(51) Int. Cl. H01L 21/311; G03F 7/00

(52) U.S. Cl. 438/702; 430/313; 257/E21.249

(57) ABSTRACT

Among other implementations, a method for manufacturing a structure on a substrate is described wherein at least one carrier structure is positioned on a substrate and at least one spacer structure is positioned on the sidewalls of the at least one carrier structure, the at least one carrier structure or the at least one spacer structure is subsequently removed and before or after the removal of the at least one spacer structure or the removal of the at least one carrier structure, an etch resistant layer is positioned in at least one of the following regions: a region not covered by the at least one carrier structure, a region not covered by the at least one spacer structure and a region not covered by the at least one carrier structure and the at least one spacer structure.

### BACKGROUND

In the manufacturing of semiconductor devices, such as, e.g., integrated circuits, memory chips, DRAM chips, microprocessors, optoelectronic devices, electromechanical devices, mask devices or bio-chips, it is often necessary to structure a substrate. A substrate can be e.g. a silicon wafer, a germanium wafer, a glass substrate or a III-V material wafer. Furthermore, the substrate can already comprise some structures which have been manufactured in previous processes.

Known processes used in the manufacturing of semiconductors can be e.g. the exposure to radiation in a lithography process, the deposition of material layers on the substrate, the etching of the substrate or the doping of the substrate with dopants. The person skilled in the art will recognize that other processes are used in the manufacturing of semiconductor devices.

### SUMMARY OF THE INVENTION

A method for manufacturing a structure on a substrate is disclosed in a first embodiment. At least one carrier structure is positioned on a substrate and at least one spacer structure is positioned on the sidewalls of the at least one carrier structure. The at least one carrier structure or the at least one spacer structure is subsequently removed and, before or after the removal, an etch resistant layer is positioned in at least one of the following regions: a region not covered by the at least one carrier structure, a region not covered by the at least one spacer structure or a region not covered by the at least one carrier structure and the at least one spacer structure.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a starting point for a first implementation of a method for manufacturing a semiconductor device of a cross section of a prestructured substrate;

FIG. 2 shows the substrate according to FIG. 1 after the removal of a carrier structure;

FIG. 3 shows the substrate according to FIG. 2 after the selective formation of an etch resistant layer;

FIG. 3A shows a top view of the substrate according to FIG. 3;

FIG. 4 shows the substrate according to FIG. 4 after the removal of spacer structures;

FIG. 5 shows the substrate according to FIG. 5 after the further processing;

FIG. 5A shows a top view of the substrate of FIG. 5;

FIG. 6 shows a starting point for a second implementation of a method for manufacturing a semiconductor device of a cross section of a prestructured substrate;

FIG. 7 shows the substrate according to FIG. 6 after a selective deposition of an etch resistant layer;

FIG. 7A shows a top view of the substrate according to FIG. 7;

FIG. 8 shows the substrate according to FIG. 8 after the removal of spacer structures;

FIG. 9 shows the substrate according to FIG. 8 after a first pattern transfer;

FIG. 10 shows the substrate according to FIG. 9 after a second pattern transfer;

FIG. 10A shows a top view of the substrate of FIG. 10;

FIG. 11 shows a starting point for a third implementation of a method for manufacturing a semiconductor device of a cross section of a prestructured substrate;

FIG. 12 shows the substrate according to FIG. 11 after a selective deposition of an etch resistant layer;

FIG. 12A shows a top view of the substrate according to FIG. 12;

FIG. 13 shows the substrate according to FIG. 12 after the removal of spacer structures;

FIG. 14 shows the substrate according to FIG. 13 after a first pattern transfer;

FIG. 14A shows a top view of the substrate of FIG. 14;

FIG. 15 shows a starting point for a fourth implementation of a method for manufacturing a semiconductor device of a cross section of a prestructured substrate;

FIG. 16 shows the substrate according to FIG. 15 after a selective deposition of a an etch resistant layer;

FIG. 17 shows the substrate according to FIG. 16 after the partial removal of the etch resistant layer;

FIG. 17A shows a top view of the substrate depicted in FIG. 17;

FIG. 18 shows the substrate according to FIG. 17 after the removal of the spacer structures;

FIG. 19 shows the substrate according to FIG. 18 after a first pattern transfer;

FIG. 19A shows a top view of the substrate of FIG. 19;

FIG. 20 shows a starting point for a fifth implementation of a method for manufacturing a semiconductor device of a cross section of a prestructured substrate;

FIG. 21 shows the substrate according to FIG. 20 after a selective deposition of an etch resistant layer;

FIG. 22 shows the substrate according to FIG. 21 after the removal of spacer structures;

FIG. 23 shows the substrate according to FIG. 22 after the removal of the encapsulating layer; and

FIG. 24 shows a flow chart of another implementation of a method for manufacturing a semiconductor device.

### DETAILED DESCRIPTION OF ILLUSTRATIVE EMBODIMENTS

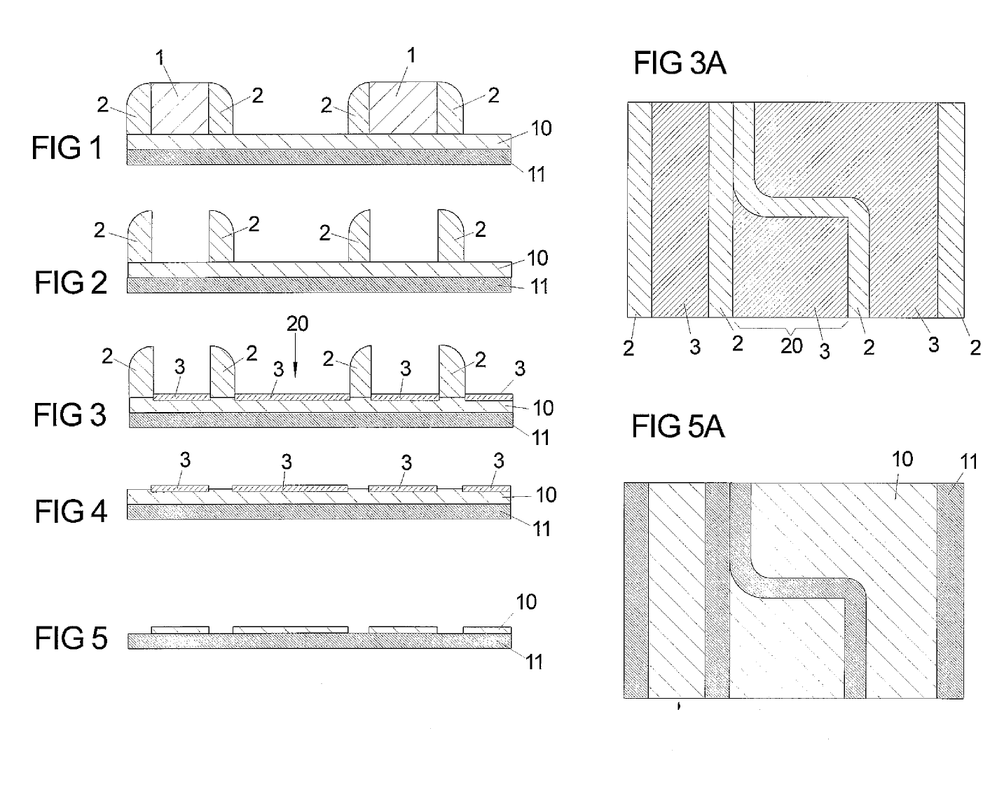

In FIG. 1 a cross section of a region in a semiconductor device is shown depicting the starting point of a first implementation of a method for manufacturing a semiconductor device. A semiconductor device can be, e.g., an integrated circuit, a memory chip, a DRAM chip, a microprocessor, an optoelectronic device, an electromechanical device, a mask device or a bio-chip.

The part shown in FIG. 1 comprises carrier structures 1 on a base substrate 10. Underneath the base substrate 10 an underlayer 11, e.g., comprising carbon or SiO₂, is positioned.

The carrier structures 10 can be manufactured by methods known in the art, e.g. in connection with pitch fragmentation techniques or double patterning techniques. The carrier structures 1 shown in FIG. 1 are essentially linear (see, e.g., top view of FIG. 3A). In alternative implementations, the carrier structures 1 can be polygonal, rectangular, pin-like or circular. The base substrate 10 can comprise, e.g., poly-silicon. In FIG. 3A (and all other top views) the depicted joined parts of the spacer structures can be twice the spacer thickness (as shown) or less. In many instances the thickness of the joined part of the spacer structures will be less than twice the individual spacer thickness.

In the implementation shown in FIG. 1 the carrier structure 1 comprises carbon. Alternative implementations of the method can use carrier structures comprising amorphous silicon or resist polymers.

On the sidewalls of the carrier structures 1, spacer structures 2 are positioned. The spacer structures 2 comprise, e.g., Si₃N₄. One possibility for manufacturing the spacer structures 2 is the deposition of spacer material on the base substrate 10 and on the carrier structures 1, followed by an anisotropic removal of the spacer material so that only the sidewalls of the carrier structures 1 remain covered with spacer material.

In FIG. 2 the cross section of FIG. 1 is shown after further processing, i.e., the carrier structures 1 have been removed. In case the carrier structures 1 comprise carbon, the removal can be obtained by an etching process using a plasma containing oxygen.

In FIG. 3 the cross section of FIG. 2 is shown after the selective oxidation (e.g., SELOX) resulting in an etch resistant layer 3 in those regions which are not covered by the spacer structure 2. The selective oxidation, e.g., shows a high growth rate on silicon and a low growth rate on silicon oxide (or silicon nitride or doped silicon).

In case the base substrate 10 comprises poly-silicon, the SiO₂ layer can be selectively oxidized in a furnace or with a plasma comprising oxygen. The process is selective since the spacer structures 2 are not covered by the etch resistant layer 3. In alternative processes the etch resistant layer 3 is selectively grown or selectively deposited on the base substrate 10.

In FIG. 3A a top view of the substrate shown in FIG. 3 depicted. As can be seen the spacer structures 2 are essentially linear. The regions between the spacers structures 2 are covered with the etch resistant layer 3. Between the spacer structures 2, a fill area 20 is shown.

In FIG. 4 the cross section of FIG. 3 is shown after the spacer structures 2 have been removed. In case the spacer structures 2 comprise Si₃N₄ this can be obtained by an etching process with hot H₃PO₄.

In FIG. 5, the cross section of FIG. 4 is shown after further processing. Here the etch resistant layer 3 has been used as a hard mask to etch the base substrate 10, i.e., the poly-silicon of the base substrate 10 has been partially removed. The underlayer 11, comprising carbon can be etched as well. Subsequently the SiO₂ of the etch resistant layer 3 is removed.

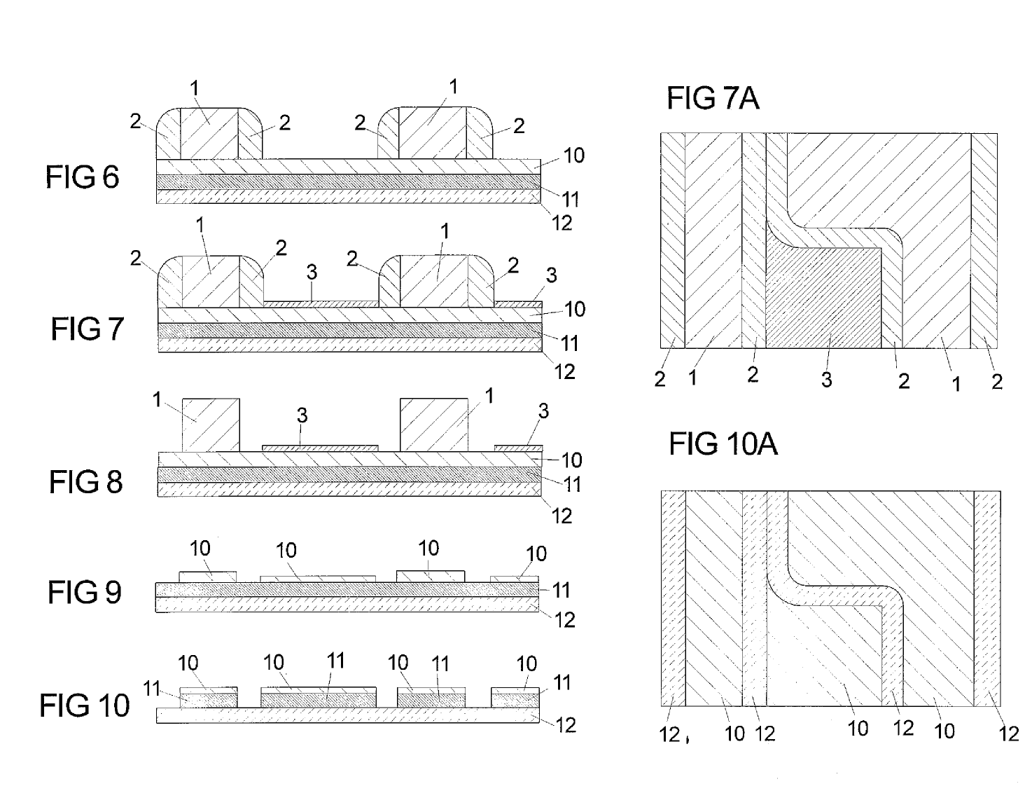

In FIG. 6 a cross section of a region in a semiconductor device is shown depicting the starting point of a second implementation of a method for manufacturing a semiconductor device.

The shown part comprises carrier structures 1, on a base substrate 10. Underneath the base substrate 10, a first underlayer 11, e.g., SiON and a second underlayer 12, e.g., carbon, are positioned.

In the second implementation the carrier structure 1 comprises SiO₂. On the sidewalls of the carrier structures 1, spacer structures 2 (e.g., comprising Si₃N₄) are positioned. Otherwise the structure shown in FIG. 6 is similar to the one in FIG. 1. For the sake of brevity reference is made to the description in connection with FIG. 1.

In FIG. 7, the cross section of FIG. 6 is shown after a further processing, i.e., a selective deposition of an etch resistant layer 3. The etch resistant layer 3 can comprise HfO₂ or ZrO₂. or Ge or Si—Ge. The etch resistant material is deposited in regions not covered by the carrier structure 1 and not covered by the spacer structures 2. In FIG. 7A, a top view of FIG. 7A is shown. This is a similar view as shown in FIG. 3A, but the structure was manufactured using different materials and different processes.

In another implementation (not shown) the carrier structure 1 can be removed before the selective deposition. In this case the resulting substrate would be in structure similar to the one depicted in FIG. 3.

In FIG. 8, the cross section of FIG. 7 is shown after the spacer structures 2 have been removed. In case the spacer structures 2 comprise Si₃N₄ this can be obtained by an etching process with hot H₃PO₄. As a difference to the first implementation, the carrier structures 1 remain in this second implementation.

In FIG. 9, the cross section of FIG. 8 is shown after a further processing. Here the etch resistant layer 3 and the carrier structures 1 have been used in a first pattern transfer as a hard mask to etch the base substrate 10, i.e., the poly-silicon of the base substrate 10 has been partially removed. The first underlayer 11 can be etched as well (not shown). Subsequently the etch resistant layer 3 is removed.

In FIG. 10, a further processing of the substrate shown in FIG. 9 is depicted. This comprises a second pattern transfer, i.e., the structuring of the first underlayer 11.

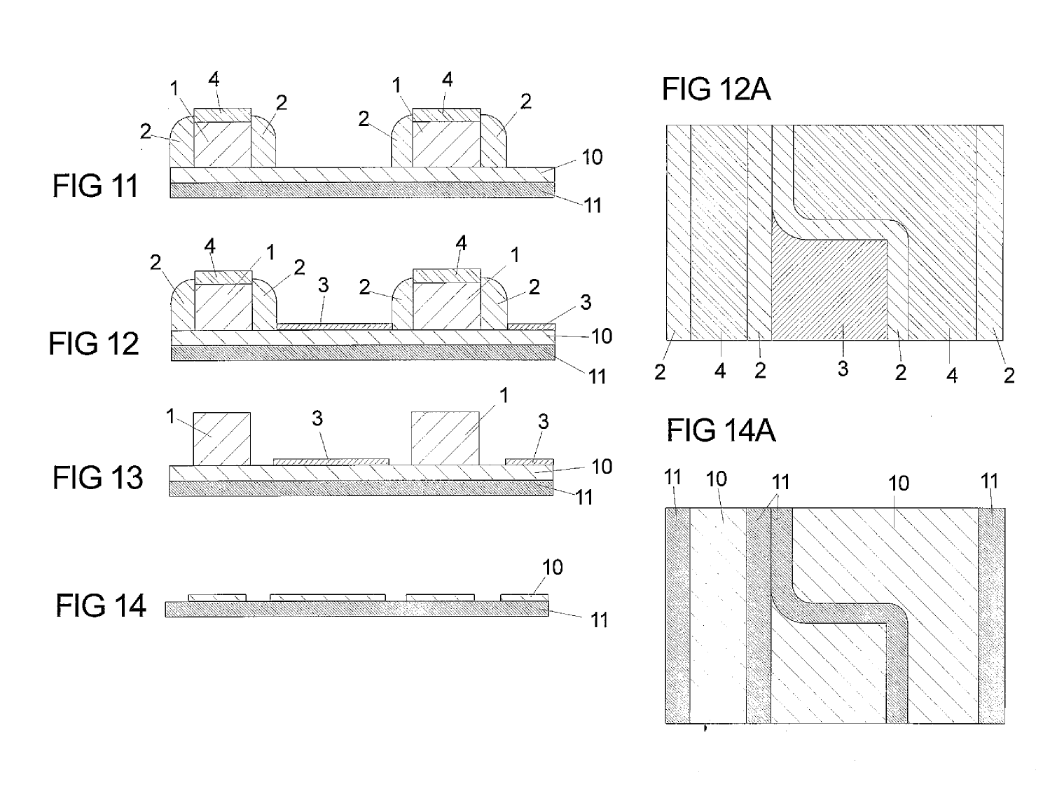

In FIG. 11, a cross section of a region in a semiconductor device is shown depicting the starting point of a third implementation of a method for manufacturing a semiconductor device. The base substrate 10 comprises amorphous silicon. Unlike in the previously described implementations, here the carrier structure 1 comprises an encapsulation layer 4 comprising, e.g., SiO₂. In alternative implementations the encapsulation layer 4 can comprise an oxide and/or a nitride. The encapsulation layer 4 can be used, e.g., as a hard mask for the etching of the carrier structure 1 or as special material to prevent growth on top of the carrier structure 1. Like in the previously described implementations at the sidewalls of the carrier structure 1 (and possibly also the sides of the encapsulation layer 4) spacers structures 2 are positioned.

The shown part comprises also a base substrate 10. Underneath the base substrate 10 is a first underlayer 11 which can comprise carbon.

In the third implementation the carrier structure 1 comprises SiO2, SiON, amorphous silicon, doped poly-Si or carbon. On the sidewalls of the carrier structures 1, spacer structures 2 (e.g., comprising Si₃N₄) are positioned. Structurally this is similar to the structure shown in FIG. 1. For the sake of brevity reference is made to the description of FIG. 1.

In FIG. 12, the cross section of FIG. 11 is shown after a further processing, i.e. a selective deposition of an etch resistant layer 3. The etch resistant layer 3 can comprise HfO₂, ZrO₂, silicon, germanium or silicon-germanium. The etch resistant material is deposited in regions not covered by the carrier structures 1 and not covered by the spacer structures 2. In FIG. 12A, a top view of FIG. 12 is shown. This is a similar view as shown in FIG. 7A, but the structures can be manufactured using different materials and different processes.

In another implementation, the carrier structure 1 with the encapsulation layer 4 can be removed before the selective deposition. In this case the resulting substrate would be in structure similar to the one depicted in FIG. 3.

In FIG. 13, the cross section of FIG. 12 is shown after the spacer structures 2 and the encapsulation layer 4 have been removed. In case the spacer structures 2 comprise Si₃N₄ this can be obtained by an etching process with hot H₃PO₄. It is possible that material can diffuse out of the carrier structures 1 into the base substrate 10 altering the etch selectivity of the base substrate 10 (not shown). A locally altered base substrate 10 could be subjected to an etch process after the removal of the carrier structure 3, the locally altered region would then be used as a mask for etching layers below.

In FIG. 14, the cross section of FIG. 13 is shown after a further processing. Here the etch resistant layer 3 and the carrier structure 1 have been used as a hard mask to etch the base substrate 10, i.e., the amorphous-silicon of the base substrate 10 has been partially removed. The hard mask may also serve to ensure the selectivity of deposition between fill and carrier areas. The underlayer 11, comprising carbon or SiO₂ can be etched as well. Subsequently the SiO₂ of the etch resistant layer 3 is removed. FIG. 14A shows a top view of the substrate depicted in FIG. 14.

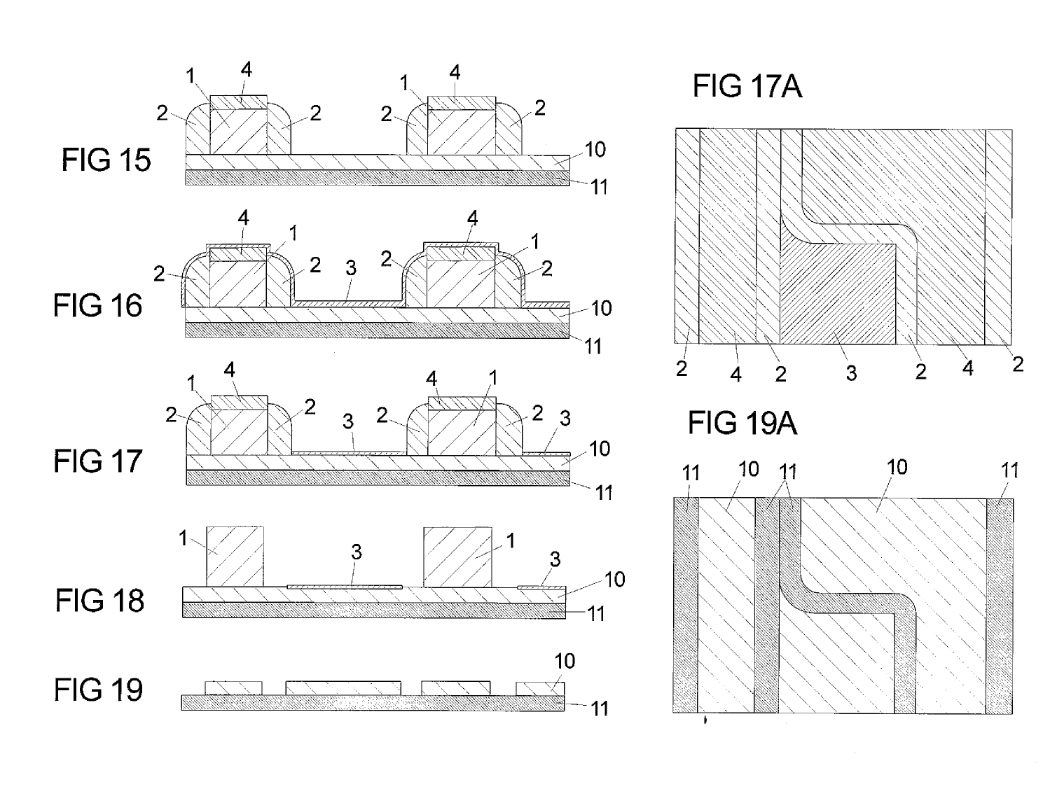

In FIG. 15, a starting point for a fourth implementation of a method for manufacturing a substrate is shown.

The starting point depicted in FIG. 15 is structurally similar to the one shown in FIG. 11. The materials in the depicted fourth implementation are the same as shown in FIG. 11, so that reference is made to the description of FIG. 11.

The substrate with spacer structure 2 and carrier structure 1 (with encapsulating layer 4) are covered with a conformal but selective deposition with, e.g., HfO₂, ZrO₂, silicon, germanium or silicon-germanium (FIG. 16) resulting in an etch resistant layer 3. Selective in this context means that more material is deposited on the substrate 10 than on the carrier structures 1 or spacer structures 2.

The deposited etch resistant layer 3 is at least partially etched, e.g., dry with isotropic component or wet, to remove the layer from the spacer structures 2 and the carrier structure 1 (or the encapsulating layer 4), as shown in FIG. 17. FIG. 17A shows a top view of the substrate shown in FIG. 17.

Like in the third implementation (FIG. 13), the spacer structures 2 are removed, as shown in FIG. 18. As shown in FIG. 19, the carrier structure 1 and the etch resistant layer 3 can be used as a hardmask to pattern the underlying layers 10, 11, e.g., SiON and C.

Alternatively, a hard mask above the carrier structure 1 can be used for the spacer process. The hard mask may be selected not only to etch the carrier, but also to prevent deposition of the fill material of etch resistant layer 3. For example, the hard mask is the same material as the spacer. Subsequently the spacer structure 2 can be removed, which is followed by a selective deposition.

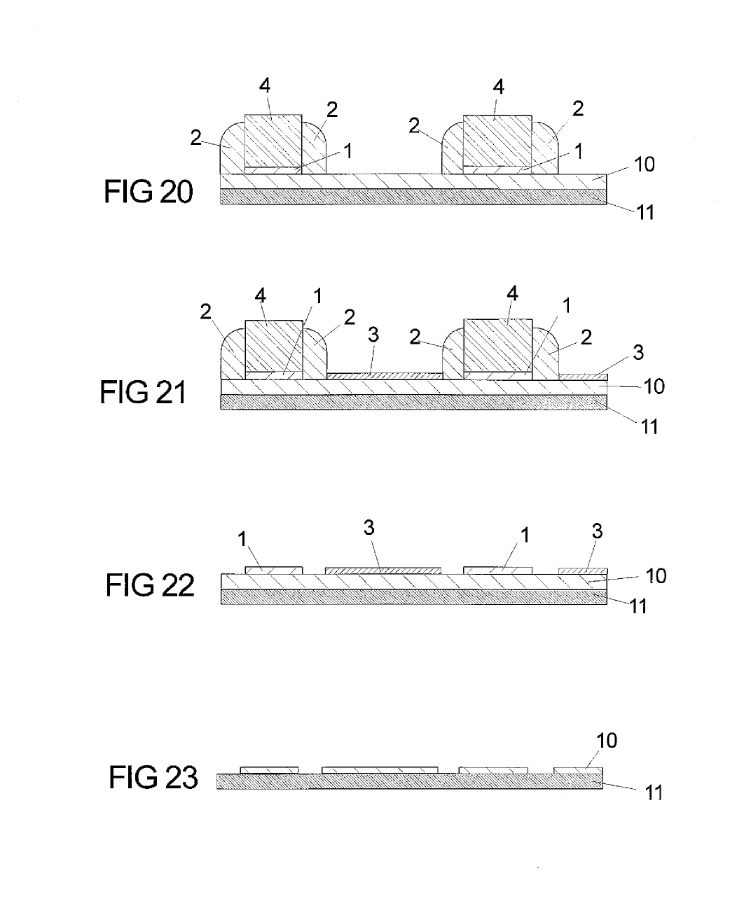

FIG. 20 shows the starting point of a fifth implementation. Like in the implementation shown in FIG. 14, an encapsulation layer 4 is positioned above a carrier structure 1. But in the fifth implementation the encapsulation layer 4 has a higher thickness than the carrier structure 1. The carrier structure 1, has in this example, a thickness which is comparable to the thickness of the etch resistant layer 3.

The process flow is then comparable to the fourth implementation. In FIG. 21 the selective deposition of the etch resistant layer 3 is shown. After the removal of the encapsulation layer 4, the carrier structure 1 and the etch resistant layer 3 can function as a hard mask (FIG. 22) to structure the layers below (FIG. 23).

The concept of the relatively thick encapsulation layer 4 can also be applied to the third embodiment.

With the shown implementations it is possible to manufacture small (e.g., sublithographic structures). The processes shown in FIGS. 1 to 23 do not necessarily imply that no further processes are carried out between the depicted situations. In other implementations, further processes, not depicted in FIGS. 1 to 23 can be performed.

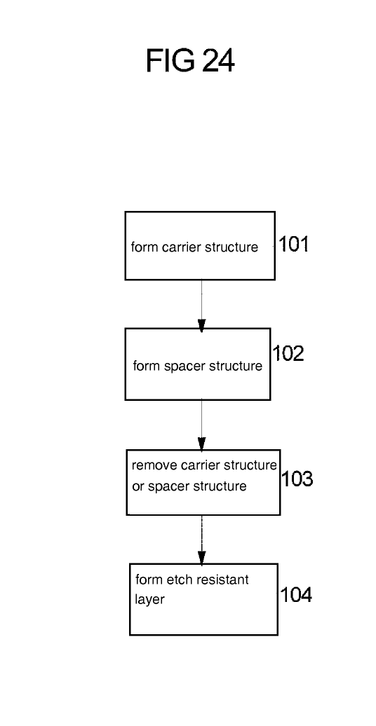

In FIG. 24 a flow chart is shown, in which a further implementation of a method for manufacturing a structure on a substrate is depicted.

In a first process 101, at least one carrier structure 1 is positioned on a substrate. In a second process 102, at least one spacer structure 2 is positioned on the sidewalls of the at least one carrier structure 1. The at least one carrier structure 1 or the at least one spacer structure 2 is subsequently removed in a process 103. In another process 104, which can take place before or after the removal of the at least one spacer structure 2 or the removal of the at least one carrier structure 1 an etch resistant layer 3 is positioned in at least one of the following regions:

a region not covered by the at least one carrier structure 1,

a region not covered by the at least one spacer structure 2, or

a region not covered by the at least one carrier structure 1 and the at least one spacer structure 2. In all cases in the fill areas (e.g., the area between the spacer structure 2) material is selectively deposited.

The person skilled in the art will recognize that between the processes 101, 102, 103, 104 other process steps might be carried out.

1. A method for manufacturing a structure on a substrate, the method comprising:
forming a carrier structure on a substrate;
forming a spacer structure on sidewalls of the carrier structure;
subsequently removing the carrier structure to expose a portion of the substrate;
after removing the carrier structure, forming an etch resistant layer in exposed regions of the substrate; and
etching the substrate using the etch resistant layer as an etch mask.

2. (canceled)

3. The method according to claim 1, wherein the carrier comprises at least one amorphous silicon, carbon, a polymer, or SiO2.

4. The method according to claim 1, wherein the spacer structure comprises at least one of Si3N4, MoN, TaN, TiN, a non-oxidized material, or an oxidized material that can be removed selectively.

5. The method according to claim 1, wherein forming the etch resistant layer comprises depositing by selective oxidation or selective deposition.

6. The method according to claim 5, wherein forming the etch resistant layer comprises performing selective oxidation, wherein the selective oxidation comprises oxidizing the substrate such that regions not covered by the carrier and the spacer structure have a different growth rate for an oxide if the substrate is subjected to oxygen.

7. The method according to claim 6, wherein oxidizing comprises forming a SiO2 layer on a silicon or germanium containing underlayer.

8. The method according to claim 5, wherein forming the etch resistant layer comprises performing a selective deposition, wherein the selective deposition comprises a deposition of a material on the exposed regions of the substrate with a higher growth rate for the material deposited than on the spacer structure.

9. The method according to claim 8, wherein the material deposited comprises at least hafnium oxide, silicon, zirconium oxide, germanium and/or silicon-germanium.

10. The method according to claim 1, further comprising after forming the etch resistant layer:
removing the spacer structure.

11. (canceled)

12. The method according to claim 1, further comprising at least partially covering the carrier structure with an encapsulation layer.

13. The method according to claim 12, wherein a thickness of the encapsulation layer is higher than a thickness of the carrier structure.

14. The method according to claim 1, wherein the substrate is part of a semiconductor device, an integrated circuit, a memory chip, a DRAM chip, a microprocessor, an optoelectronic device, an electromechanical device, a mask device and a bio-chip.

15. (canceled)

16. The method according to claim 12, wherein an encapsulation layer is positioned above the carrier structure, and wherein the encapsulation layer is removed after forming the etch resistant layer.

17. A method for manufacturing a structure on a substrate, the method comprising:
forming a carrier structure on a substrate;
forming a spacer structure on sidewalls of the carrier structure;
selectively depositing an etch resistant layer comprising hafnium, zirconium, or germanium in exposed regions of the substrate; and
etching the substrate using the etch resistant layer as an etch mask.

18. The method of claim 17, wherein a thickness of the etch resistant layer is less than a thickness of the carrier structure.

19. The method according to claim 17, wherein during etching the substrate the carrier structure acts as an etch mask.

20. A method for manufacturing a structure on a substrate, the method comprising:
forming a carrier structure on a substrate;
forming a spacer structure on sidewalls of the carrier structure;
forming an encapsulation layer on the carrier structure;
forming an etch resistant layer on a region not covered by both the encapsulation layer and the spacer structure.
removing the spacer structure after forming the etch resistant layer; and
etching the substrate using the etch resistant layer and the carrier structure as an etch mask.

21. The method according to claim 20, wherein forming the etch resistant layer comprises performing selective deposition or selective oxidation.

22. The method according to claim 20, wherein forming the etch resistant layer selectively depositing an etch resistant layer comprising hafnium, zirconium, or germanium.
